(19) United States
(12) Patent Application Publication
(10) Pub. No.: US 2021/0285830 A1
(43) Pub. Date: Sep. 16, 2021

(54) PROXIMITY AND TACTILE SENSOR

(71) Applicant: WASEDA UNIVERSITY, Tokyo (JP)

(72) Inventors: Alexander Schmitz, Tokyo (JP); Sophon Somlor, Tokyo (JP); Tito Pradhono Tomo, Tokyo (JP); Harris Kristanto, Tokyo (JP); Jinsun Hwang, Tokyo (JP); Shigeki Sugano, Tokyo (JP)

(73) Assignee: WASEDA UNIVERSITY, Tokyo (JP)

(21) Appl. No.: 16/316,159

(22) PCT Filed: Jul. 3, 2017
(86) PCT No.: PCT/JP2017/024277

§ 371 Date: Jan. 8, 2019

(30) Foreign Application Priority Data
Jul. 11, 2016 (JP) 2016-136574

(51) Int. Cl. G01L 1/12; G01B 7/24; G01D 21/02

(52) U.S. Cl. CPC G01L 1/122; G01D 21/02; G01B 7/24

(57) ABSTRACT

The sensor detects a proximity situation and applied external force in the same installation area while minimizing elements and boards included in a sensor. A proximity and tactile sensor 10 includes a body unit 11 to be attached to a detection target portion and a detection unit 12 configured to obtain approaching distance of an object to the body unit 11 and magnitude of external force. The body unit 11 includes an electrode 14 formed by a rigid body with conductivity, a magnetic body 15 integrally attached to the electrode 14, a foam 16 disposed outside the electrode 14 and magnetic body 15 and composed of an elastic body, and a magnetic sensor 17 configured to detect change in magnetic field from the magnetic body 15. The detection unit 12 includes a proximity sensing unit 22 and an external force sensing unit 23.

### TECHNICAL FIELD

The present invention relates to a proximity and tactile sensor that has both functions of a proximity sensor and tactile sensor and makes it possible to detect both of a proximity situation to an object and external force applied to the sensor in a wide range with a required minimum number of sensors.

### BACKGROUND ART

In motion control of robots working together with human beings, it is necessary from viewpoints of safety and the like to learn approaching distance to an object such as a human being within an environment around the robots and also to detect external force when the object comes into contact. As the motion control, for example, a conceivable motion control of a robot is to detect approaching distance between a movable part such as an arm of the robot and a human being around it and avoid collision with the human being in advance. Also, another conceivable motion control of a robot is, when a human being collides with the robot all of a sudden, to detect its external force, and reduce impact on the human being according to magnitude of the external force.

As a proximity sensor to detect a proximity situation with an object, a known one is a capacitive proximity sensor that detects approaching distance to the object without contact on the basis of change in capacitance of an electrode (for example, see Patent Literature 1 and 2).

As a tactile sensor to detect external force, a known one is a magnetic tactile sensor using change in magnetic field due to action of external force (for example, see Patent Literature 3). The magnetic tactile sensor includes an elastic body with a magnet provided therein and a magnetic sensor to detect a state of a magnetic field generated by the magnet, and is configured to detect, when external force is applied to the elastic body, magnitude of the external force applied to the elastic body from state change in magnetic field between the magnet and the magnetic sensor due to displacement of the magnet along with deformation of the elastic body.

### CITATION LIST

### Patent Literature

Patent Literature 1: Japanese Patent Laid-Open No. 2014-167415
Patent Literature 2: Japanese Patent Laid-Open No. 2015-94598
Patent Literature 3: Japanese Patent Laid-Open No. 2004-325328

### SUMMARY OF INVENTION

### Technical Problem

As described above, in order to maintain motion control of a robot living together with human beings, there is a need to dispose the above-described proximity sensors and the above-described tactile sensors on all of exposed parts of the robot from viewpoints of safety and the like. On top of that, in order to accurately detect a proximity situation with an object and external force, the numbers of elements and boards included in the sensors will surely increase, which prevents the robot from becoming lighter in weight. In addition, a magnetic tactile sensor with structure of Patent Literature 3 cannot be disposed at an exposed part of the robot where a capacitive proximity sensor with structure of Patent Literature 1 and 2 is disposed, and conversely the capacitive proximity sensor cannot be disposed at an exposed part of the robot where the magnetic tactile sensor is disposed. Consequently, among exposed parts of the robot where the sensors are disposed, an area where the proximity situation cannot be detected alternates with an area where the external force cannot be detected, which makes insufficient for state measurements to maintain accurate motion control of the robot in consideration of safety.

The present invention is devised in paying attention to such a problem, and its objective is to provide a proximity and tactile sensor that has elements and boards included in the sensor made to a minimum and can detect a proximity situation with an object without contact and also detect external force when the object comes into contact at the same installation area.

### Solution to Problem

In order to achieve the objective, the present invention is a proximity and tactile sensor mainly having a function as a capacitive proximity sensor to detect approaching distance to an object without contact on the basis of change in capacitance generated between the object and an electrode, and a function as a magnetic tactile sensor to detect magnitude of external force by detecting, by a magnetic sensor, change in magnetic field due to displacement of a magnetic body corresponding to the external force, in which the electrode is formed by a rigid body with conductivity, and the magnetic body is integrally attached to the electrode so that the magnetic sensor can detect the change in the magnetic field, the proximity and tactile sensor including a foam disposed outside the electrode and the magnetic body and formed by an elastic body made from a material that does not prevent the magnetic sensor from detecting the change in the magnetic field.

### Advantageous Effects of Invention

The present invention has both functions of a capacitive proximity sensor and magnetic tactile sensor and can detect a proximity situation with an object without contact and also detect external force when the object comes into contact, at the same installation area. In addition, an electrode used for detection in the capacitive proximity sensor is also used as a supporting member of a magnetic body, and when external force is applied to a flexible foam at a surface layer part, the foam elastically deforms and the external force is transmitted to some part of the electrode. Consequently, even if the magnetic body is disposed at one area of the electrode and the magnetic body is distant from a transmission part of the external force, the magnetic body can be displaced using displacement of the electrode due to rigidity, and impact of displacement of the magnetic body due to absorption of the external force within the foam can be reduced. Thus, the invention makes it possible to detect external force in a wide range while minimizing the component number and size of boards and the like including the magnetic body and magnetic sensor, and can contribute to reducing overall weight of a robot to be equipped with the sensors.

### BRIEF DESCRIPTION OF DRAWINGS

FIG. 1 is a schematic configuration diagram of a proximity and tactile sensor according to an embodiment.

FIG. 2 is a schematic exploded perspective view of a body unit of the proximity and tactile sensor.

FIGS. 3(A) and (B) are pattern diagrams for illustrating effects of the present invention using an electrode as an auxiliary member of external force transmission.

FIG. 4 is a schematic configuration diagram representing a state in which a plurality of proximity and tactile sensors are disposed.

FIG. 5 is a schematic configuration diagram of a proximity and tactile sensor according to a modified example.

### DESCRIPTION OF EMBODIMENT

Hereinafter, an embodiment of the present invention will be described in reference to the drawings.

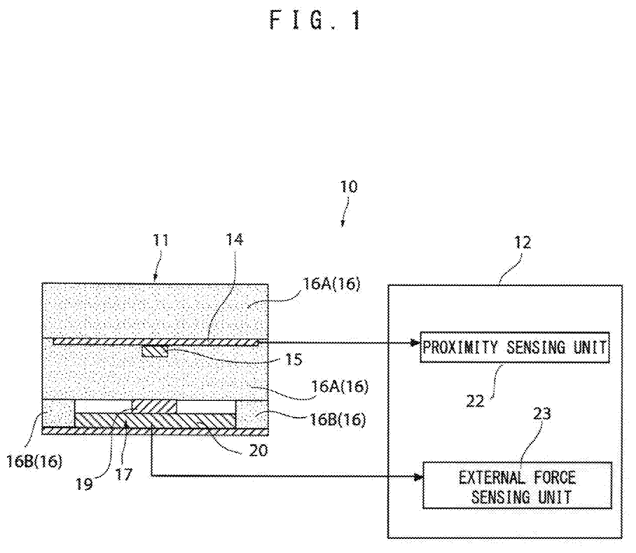

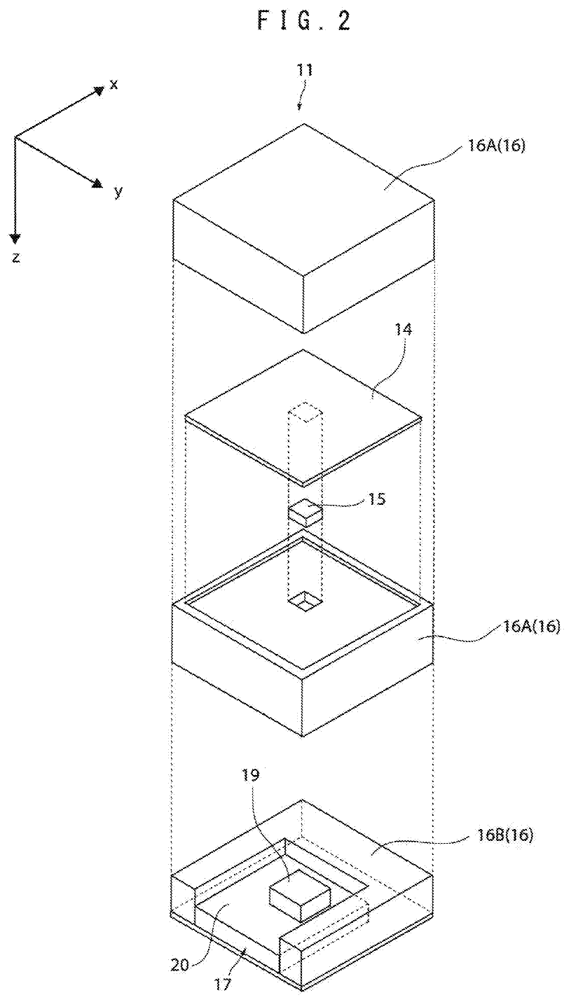

FIG. 1 shows a schematic configuration diagram of a proximity and tactile sensor according to the embodiment, and FIG. 2 shows a schematic exploded perspective view of a body unit of the proximity and tactile sensor. In the figures, a proximity and tactile sensor 10 has, at an unshown detection target portion such as a surface portion of a robot arm, a function as a proximity sensor capable of detecting an approaching state to an object such as a human being without contact, and a function as a tactile sensor capable of detecting, when external force acts on the detection target portion, an acting state of the external force.

In other words, the proximity and tactile sensor 10 includes a body unit 11 to be attached to the detection target portion and configured to generate electric signals corresponding to approaching distance to the object and magnitude of the external force, and a detection unit 12 to be electrically connected with the body unit 11 via a digital bus or the like, and configured to obtain the approaching distance and the magnitude of the external force from the electric signals.

The body unit 11 includes: an electrode 14 formed by a rigid body with conductivity and having a substantially rectangular plate shape in plan view; a magnetic body 15 fixed to one area approximately at a center of a lower surface of the electrode 14 in FIG. 1; a foam 16 disposed around the outside of the electrode 14 and magnetic body 15; and a magnetic sensor 17 disposed below the magnetic body 15 in FIG. 1 and configured to detect change in magnetic field between the magnetic body 15 and the magnetic sensor 17.

The magnetic body 15 is composed of a permanent magnet with cuboid or cubic shape although it is not particularly limited to this. As the magnetic body 15, various types of magnetic bodies and magnetic field generators can be used as long as they can generate a magnetic field of prescribed magnitude between the magnetic sensor 17 and them.

The foam 16 is formed by an elastic body made from a material that does not prevent the magnetic sensor 17 from detecting change in magnetic field and has almost no conductivity, and made up of first and second foams 16A and 16B laminated in a vertical direction in FIG. 1. The foams 16A and 16B are formed by a urethane foam, silicone foam, or the like, although they are not particularly limited to those. The first foam 16A situated on an upper side in the figure has a cuboid or cubic outer shape and is configured to contain the electrode 14 and magnetic body 15 therein. That is, in a center part of the first foam 16A, the electrode 14 with plane size little smaller than that of the first foam 16A and the magnetic body 15 integrally attached to the electrode 14 are embedded. The second foam 16B situated on a lower side in FIG. 1 is disposed to surround the outside of the magnetic sensor 17. Although thickness which is height of the first foam 16A in the vertical direction in FIG. 1 is set larger than the second foam 16B, conversely it is alright to set the second foam 16B thicker than the first foam 16A. In addition, thickness and materials of an upper part and a lower part of the electrode 14 interposed between them in the first foam 16A may be changed with each other. It is also possible to set the upper part thinner than the magnetic body 15. In other words, as long as below-described effect is obtained, sizes such as the thickness of the magnetic body 15 and first and second foams 16A and 16B can take various variations without being limited to the shown examples.

The magnetic sensor 17 adopts a known configuration including a magnetism detecting element 19 composed of a hall element, magneto-resistive element, or the like and a board 20 electrically connected with the magnetism detecting element 19, and has a structure to convert the magnetic field from the magnetic body 15 via the first foam 16A into an electric signal corresponding to magnitude of the magnetic field. In addition, the magnetism detecting element 19 is provided at three or more places in order to make it possible to detect magnitude of external force in orthogonal three-axis directions (x-, y-, and z-axis directions in FIG. 2) acting on the body unit 11, as described later, but it should be understood that they are integrated and shown as one cuboid in FIGS. 1 and 2 and the like.

The detection unit 12 includes: a proximity sensing unit 22 to be electrically connected with the electrode 14 and configured to obtain approaching distance to an object without contact and generate an electric signal corresponding to the approaching distance; and an external force sensing unit 23 to be electrically connected with the magnetic sensor 17 and configured to obtain external force acting on the first foam 16A on the basis of the electric signal from the magnetic sensor 17 and generate an electric signal corresponding to the external force.

The proximity sensing unit 22 detects approaching distance to an object without contact by a known method using a capacitive proximity sensor capable of detecting the approaching distance to the object on the basis of change in capacitance generated between the electrode 14 and the object without contact.

The external force sensing unit 23 is configured to obtain, when external force is applied to the first foam 16A, the external force in the orthogonal three-axis directions according to a displacement state in which the magnetic body 15 integrated into the electrode 14 is displaced due to elastic deformation of the first foam 16A corresponding to magnitude of the external force. Here, it is configured to calculate shear force, external force in the x- and y-axis directions in FIG. 2, and pressing force, external force in the z-axis direction in the same figure, by using known algorithm made up of prestored mathematical expressions and the like from the detected magnitudes of magnetic field corresponding to separation distance from the magnetic body 15 by respective magnetism detecting elements 19 provided at three or more places.

According to the above-described configuration, in a state in which an object is not in contact with the first foam 16A, the proximity and tactile sensor 10 functions as a capacitive proximity sensor and can detect the approaching (separation) distance to (from) the object without contact, and when some sort of object including a human being comes in contact with the first foam 16A and external force is applied, it functions as a magnetic tactile sensor and can detect magnitude of the external force in the orthogonal three-axis directions. Consequently, at the detection target portion where the body unit 11 is installed, both approaching state at the time of non-contact with the object and acting state of the external force at the time of contact with the object can be detected, and thus a non-detection area of any of the approaching state and acting state of the external force can be eliminated.

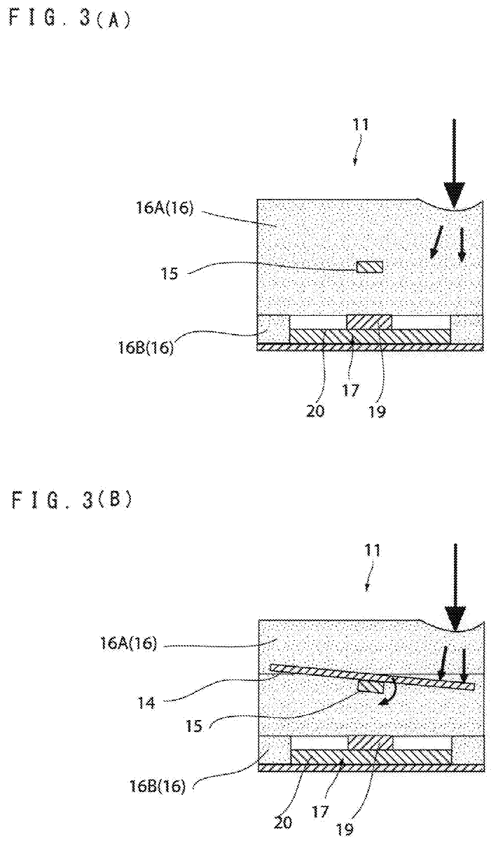

The electrode 14 is used, in addition to a function as a detection electrode when the sensor is used as a proximity sensor, as a support of the magnetic body 15 disposed relative to the magnetic sensor 17, and can function as an external force transmission auxiliary member to facilitate transmission of deformation of the first foam 16A corresponding to the magnitude of the external force to the magnetic body 15. In other words, the electrode 14 has a prescribed rigidity and can facilitate displacement of the magnetic body 15 situated on a center side of the first foam 16A by using displacement of the electrode 14 in the case where, for example, external force acts on a circumferential side of a surface of the first foam 16A (see an arrow part in each figure of FIG. 3), as shown in FIG. 3(B), in comparison with the configuration without the electrode 14 in FIG. 3(A). Thus, even if a slight external force acts on or external force acts on at a position distant from the magnetic body 15, the configuration facilitates the occurrence of displacement of the magnetic body 15 and facilitates detection of the magnitude of the external force in comparison with the configuration in FIG. 3(A). Consequently, it can minimize the numbers and sizes of the magnetic body 15 and magnetic sensors 17, detect a wider area with a small number of sensors, and contribute to making a robot or the like with the proximity and tactile sensors 10 installed thereon lighter in weight.

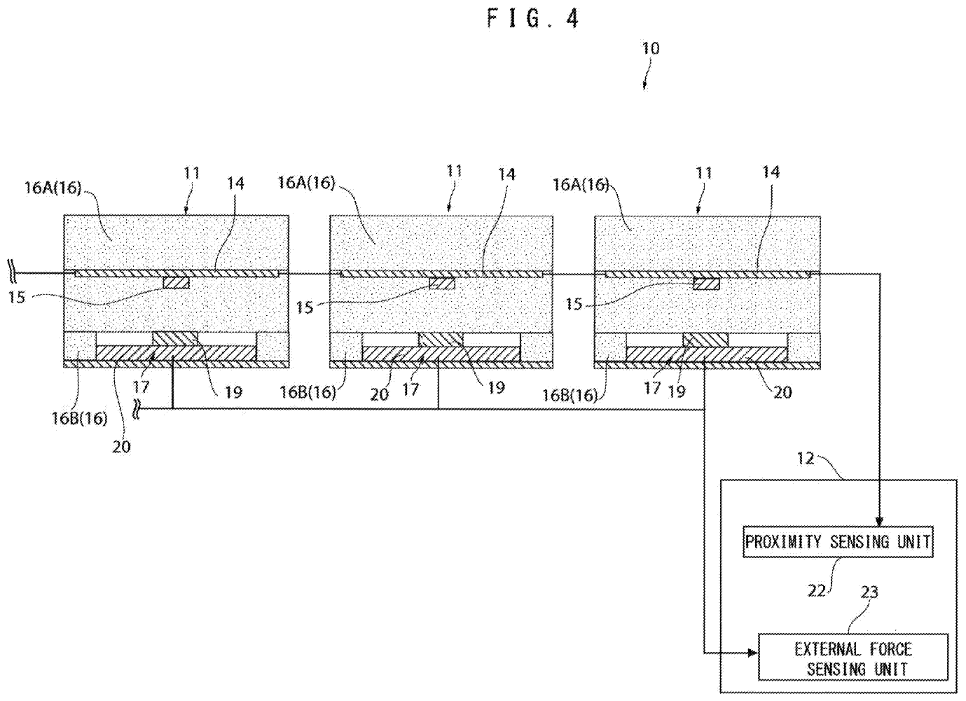

In the case where the proximity and tactile sensors 10 are installed at a plurality of detection target portions, the detection unit 12 stays one as it is but may be connected with a plurality of body units 11 as shown in FIG. 4. In this case, the electrodes 14 are electrically connected, and also the boards 20 are electrically connected via a digital bus or the like. This installation example allows for detection of the approaching state of the object and the acting state of the external force in a wider range with less wiring. In FIG. 4, although there is a gap between adjacent body units 11 in order to avoid complicating the drawing, the adjacent body units 11 can be also connected with each other in a close contact state with almost no gap.

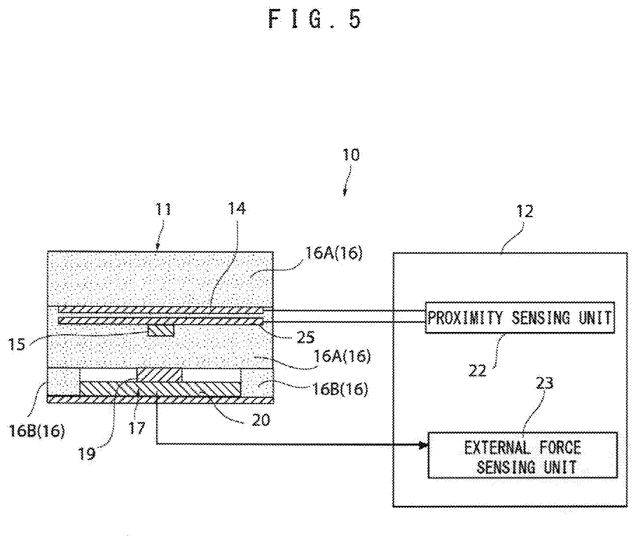

The electrode 14 is not limited to the shape and configuration of the above-described embodiment and can adopt various shapes and configurations as long as it has the prescribed rigidity and can function as an electrode of the capacitive proximity sensor. For example, the surface of the electrode 14 can be made in an uneven shape in order to enhance detection accuracy of capacitance. In addition, it may adopt a configuration to reduce noise or stray capacitance. As this configuration, it is provided, as shown in FIG. 5, with a shield electrode 25 disposed below in the figure and opposite to the electrode 14 functioning as the detection electrode, changes a board configuration of the proximity sensing unit 22, and thereby can take measures for noise reduction and the like. This case exemplifies a known aspect to connect the shield electrode 25 to the ground and a known aspect to eliminate potential difference between the electrodes by applying in-phase AC voltage to the electrode 14 and shield electrode 25. In addition, in FIG. 5, the first foam 16A lies between the electrode 14 functioning as the detection electrode and the shield electrode 25, but a member made from another non-conductive material can be laid, without being limited to the aspect.

The embodiment is shown and illustrated by taking the case of detecting the magnitude of the external force in the orthogonal three-axis directions, but the invention is not limited to it, and also allows the magnetic sensor 17 and external force sensing unit 23 to be configured so as to detect the magnitude of the external force in a one-axis direction as a minimum.

The board 20 allows other sensors such as a temperature sensor and an acceleration sensor to be further disposed thereon and the proximity and tactile sensor 10 can function as a multimode sensor.

In addition, configurations of respective units of the device in the invention are not limited to the shown configuration examples, and various modifications are possible as long as substantially the same effect is obtained.

### REFERENCE SIGNS LIST

10 Proximity and tactile sensor
11 Body unit
12 Detection unit
14 Electrode
15 Magnetic body
16 Foam
22 Proximity sensing unit
23 External force sensing unit

1. A proximity and tactile sensor having a function as a capacitive proximity sensor to detect approaching distance to an object without contact on the basis of change in capacitance generated between the object and an electrode and a function as a magnetic tactile sensor to detect magnitude of external force by detecting, by a magnetic sensor, change in magnetic field due to displacement of a magnetic body corresponding to the external force, wherein:
the electrode is formed by a rigid body with conductivity; and
the magnetic body is integrally attached to the electrode so that the magnetic sensor can detect the change in the magnetic field, the proximity and tactile sensor comprising
a foam disposed outside the electrode and the magnetic body and formed by an elastic body made from a material that does not prevent the magnetic sensor from detecting the change in the magnetic field.

2. The proximity and tactile sensor according to claim 1, wherein the foam contains the electrode and the magnetic body therein so that its elastic deformation can displace the electrode and the magnetic body.

3. A proximity and tactile sensor having a function as a capacitive proximity sensor to detect approaching distance to an object without contact on the basis of change in capacitance generated between the object and the sensor and a function as a magnetic tactile sensor to detect magnitude of external force on the basis of change in magnetic field corresponding to the external force, comprising
a body unit configured to generate an electric signal corresponding to the approaching distance or magnitude of the external force and a detection unit configured to obtain the approaching distance or the magnitude of the external force from the electric signal, wherein:
the body unit comprises an electrode formed by a rigid body with conductivity, a magnetic body integrally attached to the electrode, a foam disposed outside the electrode and the magnetic body, and a magnetic sensor disposed to detect change in magnetic field from the magnetic body, wherein
the foam is formed by an elastic body made from a material that does not prevent the magnetic sensor from detecting the change in the magnetic field; and
the detection unit comprises a proximity sensing unit configured to obtain the approaching distance from change in capacitance of the electrode, and an external force sensing unit configured to obtain the external force acting on the foam on the basis of detection by the magnetic sensor.

4. The proximity and tactile sensor according to claim 3, wherein the proximity sensing unit is configured to detect the approaching distance when the object is not in contact with the foam, whereas the external force sensing unit is configured to detect magnitude of the external force when the external force acts on the foam on the basis of displacement of the magnetic body moving integrally with the electrode along with elastic deformation of the foam.
